(19) United States
(12) Patent Application Publication
(10) Pub. No.: US 2011/0039038 A1
(43) Pub. Date: Feb. 17, 2011

(54) METHOD FOR DECORATING PERFUME BOTTLE, AND DECORATING DEVICE

(75) Inventors: Herve Ronsin, Malestroit (FR); Fabrice Soulard, Fay Aux Loges (FR)

Correspondence Address: SUGHRUE MION, PLLC, 2100 PENNSYLVANIA AVENUE, N.W., SUITE 800, WASHINGTON, DC, 20037, US

(73) Assignee: SHISEIDO INTERNATIONAL FRANCE, Paris (FR)

(21) Appl. No.: 12/988,225

(22) PCT Filed: Apr. 10, 2009
(86) PCT No.: PCT/FR2009/050667

§ 371 Date: Oct. 15, 2010

(30) Foreign Application Priority Data
Apr. 18, 2008 (FR) 0852645

(51) Int. Cl. C23C 14/58; B23K 26/00; B23K 26/06

(52) U.S. Cl. 427/596; 219/121.6; 219/121.85; 219/121.73

(57) ABSTRACT

A method of decorating a perfume bottle having a wall (11, 12, 13) that presents an outside surface (14) and an inside surface (15), at least one of the surfaces (14, 15) having a shape in relief that is complex, the method comprising at least one step of applying a coating (4, 5) to at least one portion of one of the surfaces (14, 15) of complex shape, the method further comprising a subsequent step of treating said coating, the method being characterized in that said treatment step is a marking step using a laser beam (F).

The present invention relates to a method of decorating a perfume bottle that presents a shape or a configuration that is complex, and that cannot be likened to, or resolved into, a known conventional geometrical shape, e.g. a plane, a cylinder, a sphere, a cone, etc. The present invention also relates to a decorating device that makes it possible to decorate perfume bottles of complex shape. Naturally, the field of application of the present invention is that of manufacturing and of decorating bottles, and more particularly perfume bottles, preferably made out of glass.

In the prior art, it is already known to mark the outside of glass bottles with a laser beam. In addition, it is also known to apply coatings to glass bottles. Various known types of coating exist, e.g. varnishes, lacquers, etc. In general, such coatings are situated on the outside surfaces of the bottles, and very rarely on the inside surfaces. However, when a coating is situated on the inside surface, the perfume does not come into direct contact with the inner coating so as to avoid any components being extracted and/or leached into the perfume, which components could spoil the perfume and even make it dangerous. In the prior art, it is also known to treat subsequently the coating applied to the perfume bottle. Amongst other treatments, heat treatments are known that make it possible to harden some coatings.

An object of the present invention is to improve the decorating methods already known in the prior art, particularly with regard to the subsequent second step of treating the coating.

To achieve this object, the present invention proposes a method of decorating a perfume bottle having a wall that presents an outside surface and an inside surface, at least one of the surfaces having a shape in relief that is complex, the method comprising at least one step of applying a coating to at least one portion of one of the surfaces of complex shape, the method further comprising a subsequent step of treating said coating, the method being characterized in that said treatment step is a marking step using a laser beam.

Advantageously, the application first step comprises at least one step from amongst: lacquering; varnishing; mirror coating; sintering; spraying; coating; vacuum metallizing; chemical or physical vapor deposition of metal oxides; plasma deposition; sol-gel deposition; depositing inorganic powders, etc.

In an advantageous characteristic of the present invention that may be implemented independently, i.e. on any type of perfume bottle, the laser beam passes through the wall so as to treat a coating on the inside surface. In other words, it is not necessary for the laser to penetrate into the perfume bottle through its constricted opening. The laser thus operates from the outside of the bottle through the wall thickness until it reaches the inside surface.

Naturally, it is possible to use any type of laser in the context of the decorating method of the present invention, but it turns out that a fiber laser offers the best results both with regard to accuracy of the beam and handling of the laser. It is also possible to use a YAG laser, and preferably a YAG fiber laser. Ytterbium-doped lasers are preferred for sintering. YAG fiber lasers are preferred for stripping.

In another advantageous aspect of the present invention, the laser beam is moved relative to the bottle in such a manner as to track the complex shape of the coating, the laser beam presenting a focus that is movable over a depth range that may possibly be as great as 70 mm.

Advantageously, the laser beam is moved relative to the bottle in such a manner as to track the complex shape of the coating, the laser beam being produced by a laser having a focus that is adjustable automatically as a function of the distance to the coating. This means that the performance of the laser beam is optimal, even when the distance to the target, i.e. to the inside or outside surface to be treated, varies over a determined distance that may be about 70 mm. This makes it possible to treat perfume bottles of very complex shape without having to track the surface to be treated with accuracy that is very constraining, i.e. without having to keep a constant distance between the outlet of the laser and the coating to be treated. The position of the focus of the laser beam thus varies in automatic and instantaneous manner as the surface to be treated comes closer to or goes further from the outlet of the laser beam. By means of this type of laser, it is possible to reduce considerably the cost of a perfume bottle provided with decoration that requires laser treatment.

The present invention also provides a device for implementing the above-described decorating method, the device comprising a laser having a focus, the device being characterized in that the laser includes automatic-adjustment means that make it possible to vary the position of the focus of the laser beam as a function of the distance to the coating to be treated. Preferably, the laser is a fiber laser, advantageously of YAG type.

A principle of the present invention is to use a laser to mark (or etch) coatings applied to perfume bottles of complex shape, regardless of whether the coating is on the outside or inside surface of the bottle. The laser of the present invention may be used for various types of coating treatment that are not limited to marking or etching.

The invention is described more fully below with reference to the accompanying drawings, which show an embodiment of the invention by way of non-limiting example.

In the figures:

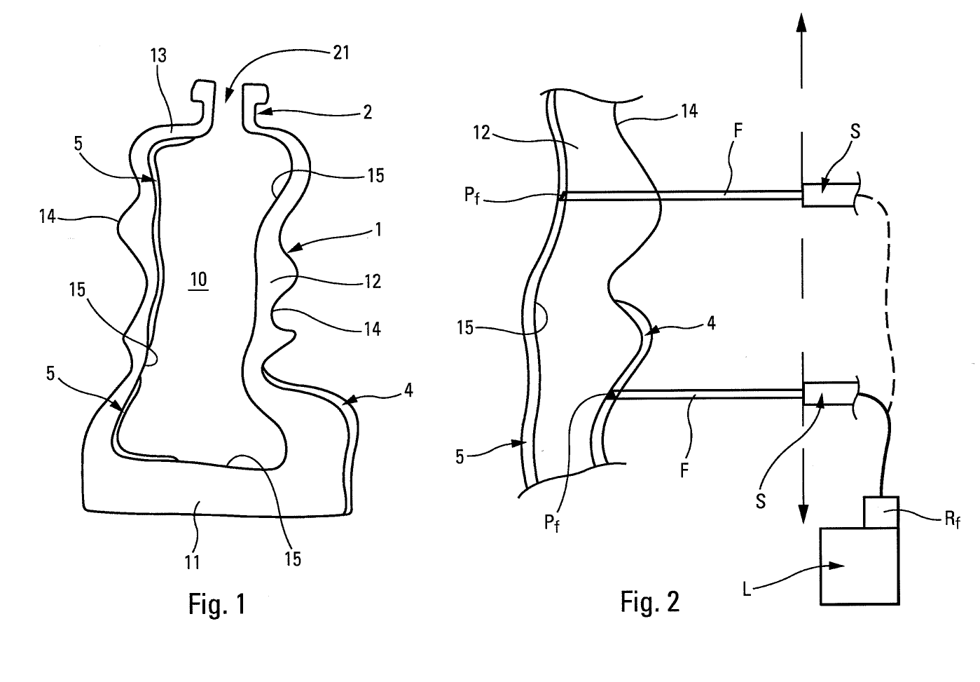

FIG. 1 is a vertical section view through a perfume bottle that may be decorated by means of the method of the present invention; and

FIG. 2 is a very diagrammatic view of a very greatly enlarged portion of a wall of a perfume bottle treated by means of a decorating device of the invention.

The perfume bottle, shown in vertical section in FIG. 1, comprises a body 1 and a neck 2. The body 1 internally defines a reservoir 10 for the perfume, which reservoir communicates with the outside through an opening 21 formed by the neck 2. The reservoir 10 is defined by a wall of the body 1, which wall may be made out of any appropriate material, e.g. glass. Advantageously, the glass may be transparent or translucent, e.g. made from a glass that is colorless or from a glass that is colored without making it opaque. The wall of the body may be divided into three distinct portions, namely a bottom 11, side faces 12, and a shoulder 13 from which the neck 2 extends. The thickness of the wall of the body may be constant, or, on the contrary, it may be irregular, as for the perfume bottle in FIG. 1. The wall of the body thus defines an outside surface 14 and an inside surface 15 that define the reservoir 10. The outside surface 14 and/or the inside surface 15 present(s) a shape that is complex in relief, which shape cannot be likened, modeled, or resolved into simple geometrical shapes, e.g. a plane, a cylinder, a sphere, a cone, an ellipsoid, etc. As can be seen in FIG. 1, the outside and inside surfaces 14 and 15 present a complex shape that is not geometrically definable. In any event, the inside surface of a glass bottle is never completely plane since it is obtained by blowing a bubble of compressed air.

Although not shown, a dispenser device, such as a pump or a valve, may be associated with the perfume bottle, so that together they constitute a perfume dispenser. The pump or the valve is mounted on the neck 2 by means of appropriate fastener means. In general, the pump includes a dip tube that extends inside the reservoir into the proximity of its bottom. The pump includes a pusher that may be pressed by means of one or more fingers so as to actuate the pump and thereby dispense the perfume extracted from the reservoir 10. All of this is entirely conventional for a perfume dispenser.

In the invention, the outside surface 14 includes a coating 4 at the bottom righthand portion of its side face 12. The coating 4 extends over a fraction only of the outside surface 14, but it may also extend over the entire surface 14. The outer coating 4 may be of various natures, e.g. a varnish, a lacquer, metallization, a sintered layer, a mirror layer, and more generally any coating that is capable of adhering to the outside surface 14. Similarly, the inside surface 15 is also provided with a coating 5 that extends over at least a fraction of the surface 15. In FIG. 1, and by way of example, there can be seen a coating 5 that is in two portions, and that extends over the left portion of the side face 12. The two portions of coating 5 are separated by a zone of the inside surface 15 that is bare. The nature of the coating 5 may be identical to that of the outer coating 4. As a function of the method of applying and obtaining the coatings 4 and 5 and of their nature and composition, it is possible to mark or etch them to a greater or lesser depth and/or intensity, but without stripping them away. The purpose is to change the appearance of the coatings without removing them. The final state of the coating(s) 4 and/or 5 may thus be considered to be the result of a decorating method comprising a first step of applying the coating, and a second step of treating said coating so that it reaches its final state. By way of example, it is possible to deposit a sol-gel on the inside surface 15 of the bottle and then mark or etch it locally by laser so as to create a pattern, an image, a logo, etc. The use of sol-gel in order to form a coating on the inside or outside of a perfume bottle is a technique that may be implemented, and thus protected, independently of the marking or etching treatment. Sol-gels use methods that make it possible to produce vitreous materials without recourse to melting.

In the invention, the second step of marking or etching is performed by means of a laser that produces a beam having a focus that reaches its target, namely the outer coating 4 and/or the inner coating 5. The purpose of bringing heat to the coating via the laser beam is to harden it, sinter it, mark it, alter it, strip it, etc.

In FIG. 2, it is possible to see how a laser beam F coming from an outlet S of a laser generator L reaches the inner coating 5 and/or the outer coating 4 with its focus Pf. It should be observed that in order to treat the inner coating 5, the laser beam F passes through the wall of the body 1 from the outside of the bottle. This is shown in the top portion of FIG. 2. In the bottom portion, it is possible to see the laser beam F having a focus Pf that is situated on the outer coating 4. It should be observed that using a laser to treat an inner coating of a perfume bottle from the outside of the bottle is a characteristic that is protectable in itself, independently of the fact that the bottle presents a shape that is optionally complex. In addition, rather than use a conventional older laser, it turns out that the use of a fiber laser gives particularly good performance. A YAG laser also gives good performance. A YAG fiber laser gives the best performances. The fiber laser is particularly advantageous as a result of the laser beam being concentrated in an optical fiber, thereby making it possible to decrease the size of the beam (F) to less than 50 micrometers (μm). A beam of 30 μm, or of less than 30 μm, makes it possible to ablate the coating cleanly, accurately, and without flaking, thereby considerably limiting the risks of perfume infiltrating between the coating and the glass. Ytterbium-doped lasers are preferred for sintering. YAG fiber lasers are preferred for stripping.

In another advantageous aspect of the invention, the laser generator L is fitted or associated with automatic-adjustment means Rf that make it possible to vary the position of the focus Pf of the laser beam F as a function of the distance to the coating to be treated. By way of example, and for identical axial positioning, as shown in FIG. 2, the adjustment means Rf make it possible to vary the focal length, i.e. positioning the focus Pf as a function of the distance between the outlet S and the coating to be treated. In FIG. 2, it can easily be observed that the focal length of the beam F treating the outer coating 4 is shorter than the focal length of the beam F treating the inner coating 5. By way of example, the adjustment means Rf may include software that makes it possible, from a scan of the shape of the coating to be treated, to vary the position of the focus Pf, e.g. by acting on the outlet lens of the laser. In a variant or in addition, the adjustment means Rf may include one or more sensors that make it possible to measure the distance between the outlet S and the coating to be treated. The values measured by the sensors are thus converted into signals that make it possible to vary the position of the focus. Other techniques may also be used to vary the position of the focus as a function of the distance to the target to be treated. Thus, by way of example, the automatic-adjustment means Rf make it possible to vary the position of the focus over a depth range that may possibly be as great as about 70 mm. Such a depth range is sufficient to treat most perfume bottles. It is rare that the side faces of a perfume bottle form hollows and/or projections having amplitudes that are greater than 40 mm. By way of example, the focus is adjusted initially to the middle value of the range of depth variation, and then is moved either side of the middle value in symmetrical or asymmetrical manner depending on the complex shape of the bottle. With such a laser with automatic focus adjustment, it is possible to treat almost all perfume bottles without having to generate complex relative movements between the outlet of the laser and the perfume bottle. This is not the situation with most fixed focus lasers that require the laser outlet to be moved in continuous and very accurate manner so that the focus is always situated on the target to be treated. A laser with automatic focus adjustment thus constitutes a decorating device that is ideal for perfume bottles that have, most particularly, outside and inside surfaces of complex shape.

Other software that treats optical-distortion phenomena similar to anamorphosis may advantageously be associated with the laser. Such software makes it possible to avoid distortion problems that could be caused by the non-incident positioning of the laser beam F relative to the coating, given the topography of the coating to be treated. By way of example, a grid formed of identical lozenges may be etched in, or stripped away from, a coating applied to a complex surface, without risk of deforming the lozenges in non-incident zones. The software makes it possible, from a scan of the shape of the coating to be treated, to influence the movement of the laser beam F, so that it takes account of the topology of the coating. The software constitutes anti-distortion means that may advantageously be associated with means for automatically adjusting the focus.

By means of the invention, it is possible to make inner and/or outer coatings of nature, composition, and shape that are very diverse, but without requiring the manipulation of the laser to be very complicated, and consequently costly.

1. A method of decorating a perfume bottle having a wall that presents an outside surface and an inside surface, at least one of the surfaces having a shape in relief that is complex, the method comprising at least one step of applying a coating to at least one portion of one of the surfaces of complex shape, the method further comprising a subsequent step of treating said coating, the method being characterized in that said treatment step is a marking step using a laser beam.

2. A decorating method according to claim 1, wherein the laser beam passes through the wall so as to treat a coating on the inside surface.

3. A decorating method according to claim 1, wherein the laser beam is produced by a fiber laser.

4. A decorating method according to claim 1, wherein the laser beam is produced by a YAG or ytterbium-doped laser.

5. A decorating method according to claim 1, wherein the laser beam is moved relative to the bottle in such a manner as to track the complex shape of the coating, the laser beam presenting a focus that is movable over a depth range of about 70 mm.

6. A decorating method according to claim 1, wherein the laser beam is moved relative to the bottle in such a manner as to track the complex shape of the coating, the laser beam being produced by a laser having a focus that is adjustable automatically as a function of the distance to the coating.

7. A decorating method according to claim 1, wherein the application first step comprises at least one step from amongst: lacquering; varnishing; mirror coating; sintering; spraying; coating; vacuum metallizing; chemical or physical vapor deposition of metal oxides; plasma deposition; sol-gel deposition; depositing inorganic powders.

8. A device for implementing the decorating method according to claim 1, the device comprising a laser having a focus, the device being characterized in that the laser includes automatic-adjustment means that make it possible to vary the focus of the laser beam as a function of the distance to the coating to be treated.

9. A decorating device according to claim 8, wherein the laser includes anti-distortion means that make it possible to avoid distortions that could be caused by the non-incident positioning of the laser beam relative to the coating, given the topography of the coating to be treated.

10. A decorating device according to claim 8, wherein the laser is a fiber laser, advantageously of YAG or ytterbium-doped type.
